(19) United States
(12) Patent Application Publication
(10) Pub. No.: US 2020/0144537 A1
(43) Pub. Date: May 7, 2020

(54) DISPLAY PANEL, ENCAPSULATING METHOD THEREOF, AND ELECTRONIC DEVICE

(71) Applicant: Wuhan China Star Optoelectronics Semiconductor Display Technology Co., Ltd., Wuhan (CN)

(72) Inventor: San ZHU, Wuhan (CN)

(21) Appl. No.: 16/323,563

(22) PCT Filed: Nov. 5, 2018
(86) PCT No.: PCT/CN2018/113935

§ 371 Date: Feb. 6, 2019

(30) Foreign Application Priority Data
Nov. 18, 2018 (CN) 201811212695.4

(51) Int. Cl. H01L 51/52

(52) U.S. Cl. CPC H01L 51/5253; H01L 27/3244; H01L 2227/323; H01L 51/5259

(57) ABSTRACT

The present invention provides a display panel, an encapsulating method thereof and an electronic device, the electronic device comprising a display panel, the display panel comprising a substrate; a thin film transistor (TFT) layer disposed on a surface of the substrate; a light emitting layer disposed on a surface of the TFT layer; a seal layer disposed on the surface of the TFT layer; a first inorganic layer covering the light emitting layer, the seal layer, and the TFT layer; an organic layer disposed on a surface of the first inorganic layer; a second inorganic layer covering the organic layer, the first inorganic layer, and the TFT layer; wherein the material of the seal layer comprises an organic photosensitive material; and wherein two or more water absorbing particles are disposed in the seal layer, and the water absorbing particles are uniformly distributed in the organic photosensitive material.

### BACKGROUND OF INVENTION

### Field of Invention

The present invention relates to the field of display technologies, and in particular, to a display panel, encapsulating method thereof and electronic device.

### Description of Prior Art

An organic light-emitting diode (OLED) is also known as an organic electro-laser display and an organic light-emitting semiconductor. OLED display technology has the advantages of being self-luminous, wide viewing angles, almost infinite contrast, low power consumption and high reaction speed, etc. An OLED display is a display made of organic light-emitting diodes. The OLED display has the advantages of no need for a backlight, high contrast, thin thickness, wide viewing angles, fast response times, can be used for flexible panels, wide temperature range, simple structure and process and so on, so it is considered to be next generation mainstream flat panel display.

OLEDs can be fabricated on flexible substrates for flexible display, and therefore are recognized as the most promising lighting and display technologies in next generation. Compared with LCD display technology, the lighting materials used in OLED displays are extremely sensitive to water and oxygen, which will shorten its service life.

In order to better develop flexible OLED display technology, there are specific encapsulating requirements of flexible OLEDs. On one hand, the encapsulation structure is required to have good water and oxygen barrier properties, and on the other hand, the encapsulation structure is required to have flexible and bendable characteristics. This makes the traditional rigid encapsulation structure unable to meet the requirements, therefore, the thin film encapsulating technology which can better adapt to the development of OLED technology came into being.

At present, a mature thin film encapsulating structure is formed by alternately depositing inorganic thin film layers and organic polymer thin film layers. The inorganic thin film layers have a good water and oxygen barrier properties, but do not have good film forming properties and flatness. Commonly used materials of inorganic thin film layers include transparent oxide thin film materials (alumina, silicon oxide, zirconium oxide, etc.), silicon nitride series, and the like. The organic polymer layers have a good film forming properties, uniformity, and surface flatness, and further have improving film stress and covering particles properties. Commonly used materials of organic polymer film are acrylic polymers and epoxy polymers. The inorganic films and the organic films are alternately formed into a film stack to constitute a complementary water and oxygen isolation unit, which is a good composite protective layer for the OLED lighting material. However, because the polymer of the organic layers has poor water and oxygen blocking properties, in actual design process, it is important to ensure that the organic layer cannot be in contact with air. Therefore, it is necessary to make sure the inorganic film layers cover the organic film layers, and the polymer should also be leveled into a film in a specified area during the leveling process of the organic polymer. However, in practice, since the uniformity of the surface energy of the film-forming substrate and the organic polymer is uncontrollable, the polymer cannot be well leveled in a specified region. In order to achieve leveling in a specified area, a seal layer (dam) is usually prepared on a periphery of the organic layer to act as a “water barrier”, so that the polymer could form a film in a specified area to ensure precision of the films.

The current seal layer is formed by using an organic substance such as photosensitive polyimide. In general, organic polymers tend to have poor barrier properties to water and oxygen, so that water and oxygen may pass through the seal layer and come into the substrate, and cause encapsulation failures. Therefore, designing a new type of display panel has become a difficult problem to be solved in a thin film encapsulation.

### Technology Problems

In the prior art, due to the poor barrier performance of the plastic seal layer to water and oxygen, water and oxygen can easily come into the substrate through the seal layer, thereby causing technical problems such as encapsulation failures and short service life of the electronic device and so on.

### SUMMARY OF THE INVENTION

The present invention provides a display, comprising: a substrate; a TFT thin film transistor (TFT) layer disposed on a surface of the substrate; a light emitting layer disposed on a surface of the TFT layer away from the substrate; a seal layer disposed on the surface of the TFT layer away from the substrate, the seal layer being annular, and surrounding the light emitting layer; a first inorganic layer covering the light emitting layer, the seal layer, and the TFT layer between the light emitting layer and the seal layer; an organic layer disposed on a surface of the first inorganic layer away from the substrate, and surrounded by the seal layer; a second inorganic layer covering the organic layer, the first inorganic layer, and the TFT layer outside the first inorganic layer; wherein the material of the seal layer comprises an organic photosensitive material; and wherein two or more water absorbing particles are disposed in the seal layer, and the water absorbing particles are uniformly distributed in the organic photosensitive material.

Further, between the light emitting layer and the seal layer is a gap; a portion of the first inorganic layer is positioned corresponding to the gap, one side of which is attached to the TFT layer, and another side of which is attached to a first side of the organic layer; and a portion of the second inorganic layer is positioned corresponding to the gap, one side of which is attached to a second side of the organic layer, and another side of which forms a groove.

Further, the TFT layer comprises a TFT device; and/or, the light emitting layer comprises an organic light emitting diode (OLED) device; and/or the first inorganic layer and the second inorganic layer comprise at least one of a silicon oxide, a silicon nitride, and an aluminum oxide; and/or, the organic layer comprises at least one of a silicone resin and an acrylic resin.

Further, a thickness of each of the first inorganic layer and the second inorganic layer ranges from 0.3 um to 3 um; and a thickness of the organic layer ranges from 2 um to 15 um.

Further, a material of the water absorbing particles comprises one or more of polyacrylic acid, polyacrylamide, polyacrylonitriles, polyvinyl alcohols, polyvinyl acetates, polyoxyethylenes, or a derivative of any one of these materials.

The present invention further provides an electronic device comprising the display panel described above.

The present invention further provides a encapsulating method of a display panel comprising following steps: S1: a step of preparing a seal material including preparing a seal liquid film containing water absorbing particles; S2: a step of preparing a TFT layer, wherein a TFT layer is formed on a surface of a substrate to form a TFT substrate; S3: a step of preparing a light emitting layer, wherein a light emitting device is formed on an upper surface of the TFT layer to form a light emitting layer; S4: a step of preparing a seal layer, wherein the liquid film is applied to an upper surface of the TFT layer to form a seal layer surrounding the light-emitting layer; S5: a step of preparing a first inorganic layer including disposing a first inorganic layer on the upper surface of the TFT layer to cover the light emitting layer, the seal layer, and the TFT layer between the light emitting layer and the seal layer; S6: a step of preparing an organic layer, including disposing an organic layer on an upper surface of the first inorganic layer, wherein the organic layer is surrounded by the seal layer; and, S7: a step of preparing a second inorganic layer, including disposing a second inorganic layer on the upper surface of the TFT layer to cover the organic layer, a portion of the first inorganic layer, and the TFT layer outside the first inorganic layer.

Further, the step of preparing a seal material comprises following steps: S11: a step of selecting main material, including providing a liquid organic photosensitive material; S12: a step of adding particles, including adding two or more water absorbing particles to the organic photosensitive material; S13: a step of a stirring, wherein the organic photosensitive material is subjected to a stirring treatment, so that the water absorbing particles are uniformly distributed in the organic photosensitive material; and S14: a step of producing liquid film, wherein the seal liquid film is obtained.

Further, the mass percentage of the water absorbing particles in the seal liquid film ranges from 0 to 50%.

Further, the step of preparing a seal layer comprises the following steps: S41: a step of coating and positioning, including locating and ascertaining a preset coating position corresponding to a peripheral region of the light emitting layer on the upper surface of the TFT layer; S42: a step of coating a liquid film, including applying the seal liquid film to the preset coating position; S43: a step of developing, including performing exposure and development processing on the seal liquid film; and S44: a step of forming a seal layer, including forming an annular seal layer surrounding the light emitting layer.

### Advantageous Effects

The present invention adds water absorbing particles to the seal layer in the prior art, so that the penetration path of water and oxygen entering the seal layer is extended, thereby making the water and oxygen difficult to enter. As a result, the penetration effect of water and oxygen is suppressed, the encapsulation effect is improved, the utility is enhanced, and the service life of the electronic device is prolonged.

### BRIEF DESCRIPTION OF DRAWINGS

FIG. 1 is a schematic diagram of a display panel according to an embodiment of the present invention;

FIG. 2 is a flowchart of a method for encapsulating a display panel according to an embodiment of the present invention;

FIG. 3 is a flow chart showing steps of preparing a seal material according to an embodiment of the present invention;

FIG. 4 is a flowchart showing steps of setting a seal layer according to an embodiment of the present invention.

Some components are identified as follows:

1, a substrate;

2, a TFT layer;

3, a light-emitting layer;

4, a seal layer; 41, water absorbing particles; 42, organic photosensitive materials;

5, a first inorganic layer;

6, an organic layer; 61, a first surface; 62, a second surface;

7, a second inorganic layer;

8, a groove.

### DETAILED DESCRIPTION OF PREFERRED EMBODIMENTS

The preferred embodiments of the present invention are described in detail below with reference to the accompanying drawings, to present a complete description of the technical contents of the present invention to those skilled in the art, to demonstrate that the present invention can be implemented, to make the technical content disclosed by the present invention clearer, and to make it apparent to those skilled in the art to understand how to practice the present invention. The present invention, however, can be embodied in many different forms of embodiments, and the scope of the present invention is not limited to the embodiments described herein. The description of the embodiments below is not intended to limit the scope of the invention.

In the drawings, structurally identical components are denoted by the same reference numerals, and structural or functionally similar components are denoted by like reference numerals. Moreover, the size and thickness of each component shown in the drawings are arbitrarily shown for ease of understanding and description, and the present invention does not limit the size and thickness of each component.

When a component is described as “on” another component, the component can be placed directly on the other component; there may also be an intermediate component on which the component is placed and which is placed on another component. When a component is described as “mounted to”, “connected to” or “disposed on” another component, it can be understood as either “mounting”, “connecting” or “disposing” directly, or a component is “mounted to”, “connected to” or “disposed on” another component through an intermediate component.

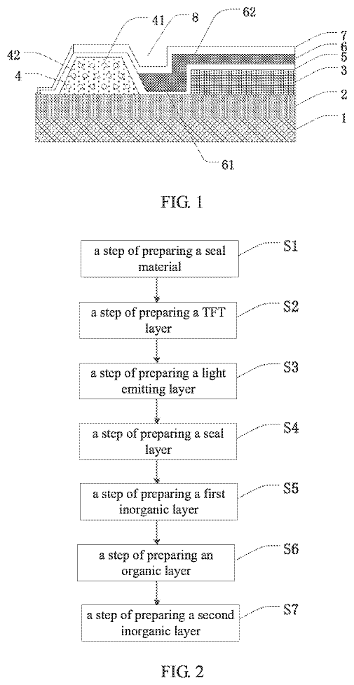

As shown in FIG. 1, the present embodiment provides a display panel comprising: a substrate 1, a TFT layer 2, a light emitting layer 3, a seal layer 4 (Dam), a first inorganic layer 5, an organic layer 6, and a second inorganic layer 7. The TFT layer 2 is disposed on the upper surface of the substrate 1; the light emitting layer 3 is disposed on the upper surface of the TFT layer 2; the seal layer 4 is disposed above the TFT layer 2, and there is a gap between the light emitting layer 3 and the seal layer 4; the first inorganic layer 5 covers the seal layer 4, the light emitting layer 3, and the gap between the seal layer 4 and the light emitting layer 3; the organic layer 6 is disposed on the light emitting layer 3 and surrounded by the seal layer 4; the second inorganic layer 7 covers the first inorganic layer 5, the organic layer 6, and the TFT layer 2 outside the first inorganic layer 5.

The material of the seal layer 4 comprises an organic photosensitive material 42, and in two or more water absorbing particles 41 are disposed in the seal layer 4, and the water absorbing particles 41 are uniformly distributed in the organic photosensitive material 42.

The first inorganic layer 5 has a portion positioned corresponding to the gap, one side of which is attached to the TFT layer 2, and another side of which is attached to a first side 61 of the organic layer 6; and the second inorganic layer 7 has a portion positioned corresponding to the gap, one side of which is attached to a second side 62 of the organic layer 6, and another side of which forms a groove 8.

The TFT layer 2 comprises a TFT device; and/or, the light emitting layer 3 comprises an OLED device; and/or the first inorganic layer 5 and the second inorganic layer 7 comprise at least one of a silicon oxide, a silicon nitride, and an aluminum oxide; and/or, the organic layer 6 comprises at least one of a silicone resin and an acrylic resin.

A thickness of each of the first inorganic layer 5 and the second inorganic layer 7 ranges from 0.3 um to 3 um; and a thickness of the organic layer 6 ranges from 2 um to 15 um.

The inorganic layer has a good water and oxygen barrier properties, but its disadvantage is that it does not have good film forming properties and the flatness, so it covers the seal layer 4 to block water and oxygen.

A material of the water absorbing particles comprises one or more of polyacrylic acid, polyacrylamide, polyacrylonitriles, polyvinyl alcohols, polyvinyl acetates, polyoxyethylenes, or a derivative of any one of these materials.

The organic polymer layer 6 has good film forming properties, uniformity and surface flatness, and further has the functions of improving film stress and covering particles. The organic polymer layer 6 covers the upper surface of the first inorganic layer 5 and the lower surface of the second inorganic layer 7, the entire outer surface of the organic layer 6 is completely covered by the seal layer 4, the first inorganic layer 5 and the second inorganic layer 7 and isolated from water and air, thereby improving the film forming properties of the first inorganic layer 5 and technical problems with poor flatness. In this embodiment, the inorganic layers and the organic layers are alternately formed into a film stack, and the respective advantages are used to block water and oxygen and form a composite protective layer of the OLED lighting material, thereby improving the encapsulating effect and prolonging the service life of the OLED device.

The present invention adds water absorbing particles to the seal layer in the prior art, so that the penetration path of water and oxygen entering the seal layer is extended, thereby making the water and oxygen difficult to enter. As a result, the penetration effect of water and oxygen is suppressed, the encapsulation effect is improved, the utility is enhanced, and the service life of the electronic device is prolonged. As shown in FIG. 2, the embodiment further provides a method for encapsulating a display panel, which specifically includes the following steps S1 to S7.

S1: a step of preparing a seal material including preparing a seal liquid film containing water absorbing particles; S2: a step of preparing a TFT layer, wherein a TFT layer 2 is formed on a surface of a substrate 1 to form a TFT substrate; S3: a step of preparing a light emitting layer, wherein a light emitting device is formed on an upper surface of the TFT layer 2 to form a light emitting layer 3; S4: a step of preparing a seal layer, wherein the liquid film is applied to an upper surface of the TFT layer 2 to form a seal layer 4 surrounding the light-emitting layer 3; S5: a step of preparing a first inorganic layer including disposing a first inorganic layer 5 on the upper surface of the TFT layer 2 to cover the light emitting layer 3, the seal layer 4, and the TFT layer 2 between the light emitting layer 3 and the seal layer 4; S6: a step of preparing an organic layer, including disposing an organic layer 6 on an upper surface of the first inorganic layer 5, wherein the organic layer 6 is surrounded by the seal layer 4; and S7: a step of preparing a second inorganic layer, including disposing a second inorganic layer 7 on the upper surface of the TFT layer 2 to cover the organic layer 6, a portion of the first inorganic layer 5, and the TFT layer 2 outside the first inorganic layer 5.

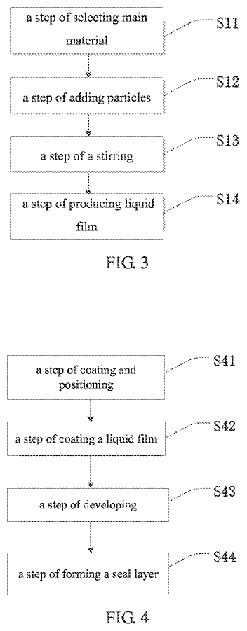

As shown in FIG. 3, the step of preparing a seal material comprises following steps: S11: a step of selecting main material, including providing a liquid organic photosensitive material 42; S12: a step of adding particles, including adding two or more water absorbing particles 41 to the organic photosensitive material 42; S13: a step of a stirring, wherein the organic photosensitive material 42 is subjected to a stirring treatment, so that the water absorbing particles 41 are uniformly distributed in the organic photosensitive material 42; and S14: a step of producing liquid film, wherein the seal liquid film is obtained.

The mass percentage of the water absorbing particles 41 in the seal liquid film ranges from 0 to 50%. In the present embodiment, the mass percentage of the water absorbing particles 41 in the seal liquid film is 5%.

As shown in FIG. 4, the step of preparing a seal layer comprises the following steps: S41: a step of coating and positioning, including locating and ascertaining a preset coating position corresponding to a peripheral region of the light emitting layer 3 on the upper surface of the TFT layer 2; S42: a step of coating a liquid film, including applying the seal liquid film to the preset coating position; S43: a step of developing, including performing exposure and development processing on the seal liquid film; and S44: a step of forming a seal layer, including forming an annular seal layer surrounding the light emitting layer 3.

A material of the water absorbing particles 41 comprises one or more of polyacrylic acid, polyacrylamide, polyacrylonitriles, polyvinyl alcohols, polyvinyl acetates, polyoxyethylenes, or a derivative of any one of these materials. The material of the organic photosensitive material 42 comprises an organic substance such as photosensitive polyimide.

The inorganic layer has a good water and oxygen barrier properties, but its disadvantage is that it does not have good film forming properties and the flatness, so it covers the seal layer 4 to block water and oxygen. The material of the first inorganic layer 5 and the second inorganic layer 7 includes a transparent oxide thin film material (aluminum oxide, silicon oxide, zirconium oxide, etc.), a silicon nitride series, or the like. The thickness of the first inorganic layer 5 and the second inorganic layer 7 ranges from 0.3 um to 3 um; and the thickness of the organic layer 6 ranges from 2 um to 15 um.

The organic polymer layer 6 has a good film forming properties, uniformity and surface flatness, and further has the functions of improving film stress and covering particles. The organic polymer layer 6 covers the upper surface of the first inorganic layer 5 and the lower surface of the second inorganic layer 7, the entire outer surface of the organic layer 6 is completely covered by the seal layer 4, the first inorganic layer 5 and the second inorganic layer 7 and isolated from water and air, thereby improving the film forming properties of the first inorganic layer 5 and technical problems with poor flatness. In this embodiment, the inorganic layers and the organic layers are alternately formed into a film stack, and the respective advantages are used to block water and oxygen and form a composite protective layer of the OLED lighting material, thereby improving the encapsulating effect and prolonging the service life of the OLED device.

The encapsulating method of the present invention adds water absorbing particles to the seal layer in the prior art, so that the penetration path of water and oxygen entering the seal layer is extended, thereby making the water and oxygen difficult to enter. As a result, the penetration effect of water and oxygen is suppressed, the encapsulation effect is improved, the operation is simplified, the cost is decreased, and the utility is improved.

Further, the embodiment also provides an electronic device, including the foregoing display panel, wherein the electronic device can be used to display data such as text, pictures, images, and the like, and can be used as an interface for the electronic device to communicate with users.

The electronic device of the present invention adds water absorbing particles to the seal layer in the edge of the display panel, thereby preventing water and oxygen from coming into the organic layer of the display panel, and the service life of the display panel and the electronic device is prolonged.

The present invention adds water absorbing particles to the seal layer in the prior art, so that the penetration path of water and oxygen entering the seal layer is extended, thereby making the water and oxygen difficult to enter. As a result, the penetration effect of water and oxygen is suppressed, the encapsulation effect is improved, the utility is enhanced, and the service life of the electronic device is prolonged.

The above description is only a preferred embodiment of the present invention. It should be noted that a number of modifications and variations can be made by those skilled in the art without departing from the principles of the invention, and such modifications and variations are also considered to be within the scope of the invention.

1. A display panel, comprising:
a substrate;
a thin film transistor (TFT) layer disposed on a surface of the substrate;
a light emitting layer disposed on a surface of the TFT layer away from the substrate;
a seal layer disposed on the surface of the TFT layer away from the substrate, the seal layer being annular and surrounding the light emitting layer;
a first inorganic layer covering the light emitting layer, the seal layer, and the TFT layer between the light emitting layer and the seal layer;
an organic layer disposed on a surface of the first inorganic layer away from the substrate and surrounded by the seal layer;
a second inorganic layer covering the organic layer, the first inorganic layer, and the TFT layer outside the first inorganic layer;
wherein the material of the seal layer comprises an organic photosensitive material; and
wherein two or more water absorbing particles are disposed in the seal layer, and the water absorbing particles are uniformly distributed in the organic photosensitive material.

2. The display panel according to claim 1, wherein:
between the light emitting layer and the seal layer is a gap;
a portion of the first inorganic layer is positioned corresponding to the gap, one side of which is attached to the TFT layer, and another side of which is attached to a first side of the organic layer; and
a portion of the second inorganic layer is positioned corresponding to the gap, one side of which is attached to a second side of the organic layer, and another side of which forms a groove.

3. The display panel according to claim 1, wherein:
the TFT layer comprises a TFT device; and/or,
the light emitting layer comprises an organic light emitting diode (OLED) device; and/or
the first inorganic layer and the second inorganic layer comprise at least one of a silicon oxide, a silicon nitride, and an aluminum oxide; and/or,
the organic layer comprises at least one of a silicone resin and an acrylic resin.

4. The display panel according to claim 1, wherein:
a thickness of each of the first inorganic layer and the second inorganic layer ranges from 0.3 um to 3 um; and
a thickness of the organic layer ranges from 2 um to 15 um.

5. The display panel according to claim 1, wherein:
a material of the water absorbing particles comprises one or more of polyacrylic acid, polyacrylamide, polyacrylonitriles, polyvinyl alcohols, polyvinyl acetates, polyoxyethylenes, or a derivative of any one of these materials.

6. An electronic device comprising the display panel of claim 1.

7. A encapsulating method of a display panel comprising following steps:
S1: a step of preparing a seal material including preparing a seal liquid film containing water absorbing particles;
S2: a step of preparing a thin film transistor (TFT) layer, wherein a TFT layer is formed on a surface of a substrate to form a TFT substrate;
S3: a step of preparing a light emitting layer, wherein a light emitting device is formed on an upper surface of the TFT layer to form a light emitting layer;
S4: a step of preparing a seal layer, wherein the liquid film is applied to an upper surface of the TFT layer to form a seal layer surrounding the light-emitting layer;
S5: a step of preparing a first inorganic layer including disposing a first inorganic layer on the upper surface of the TFT layer to cover the light emitting layer, the seal layer, and the TFT layer between the light emitting layer and the seal layer;
S6: a step of preparing an organic layer, including disposing an organic layer on an upper surface of the first inorganic layer, wherein the organic layer is surrounded by the seal layer; and
S7: a step of preparing a second inorganic layer, including disposing a second inorganic layer on the upper surface of the TFT layer to cover the organic layer, a portion of the first inorganic layer, and the TFT layer outside the first inorganic layer.

8. The encapsulating method of a display panel according to claim 7, wherein:
the step of preparing a seal material comprises following steps:
S11: a step of selecting main material, including providing a liquid organic photosensitive material;
S12: a step of adding particles, including adding two or more water absorbing particles to the organic photosensitive material;
S13: a step of a stirring, wherein the organic photosensitive material is subjected to a stirring treatment, so that the water absorbing particles are uniformly distributed in the organic photosensitive material; and
S14: a step of producing liquid film, wherein the seal liquid film is obtained.

9. The encapsulating method of a display panel according to claim 7, wherein:
the mass percentage of the water absorbing particles in the seal liquid film ranges from 0 to 50%.

10. The encapsulating method of a display panel according to claim 7, wherein:
the step of preparing a seal layer comprises the following steps:
S41: a step of coating and positioning, including locating and ascertaining a preset coating position corresponding to a peripheral region of the light emitting layer on the upper surface of the TFT layer;
S42: a step of coating a liquid film, including applying the seal liquid film to the preset coating position;
S43: a step of developing, including performing exposure and development processing on the seal liquid film; and
S44: a step of forming a seal layer, including forming an annular seal layer surrounding the light emitting layer.

11. An electronic device comprising the display panel of claim 2.

12. An electronic device comprising the display panel of claim 3.

13. An electronic device comprising the display panel of claim 4.

14. An electronic device comprising the display panel of claim 5.

15. The encapsulating method of a display panel according to claim 8, wherein:
the mass percentage of the water absorbing particles in the seal liquid film ranges from 0 to 50%.
